(19) United States
(12) Patent Application Publication
(10) Pub. No.: US 2005/0282355 A1
(43) Pub. Date: Dec. 22, 2005

(54) High density bonding of electrical devices

(76) Inventors: David N. Edwards, La Canada, CA (US); Jason Munn, West Covina, CA (US); Kouroche Kian, Altadena, CA (US); Reza Mehrabi, Tujunga, CA (US); Ian J. Forster, Chelmsford (GB); Thomas Craig Weakley, Simpsonville, SC (US)

Correspondence Address: JONATHAN A. PLATT;RENNER, OTTO, BOISSELLE & SKLAR, LLP, 19th Floor, 1621 Euclid Avenue, Cleveland, OH, 44115, US

(21) Appl. No.: 10/872,235

(22) Filed: Jun. 18, 2004

(51) Int. Cl. H01L 21/44; H01L 21/30; H01L 21/48; H01L 21/46; H01L 21/50

(52) U.S. Cl. 438/455; 438/106

(57) ABSTRACT

A method of thermocompressive bonding of one or more electrical devices using individual heating elements and a resilient member to force the individual heating elements into compressive engagement with the electrical devices is provided. The individual heating elements may be Curie-point heating elements or conventional resistive heating elements. A method of thermocompressive bonding of one or more electrical devices using a transparent flexible platen and thermal radiation is also provided. In one embodiment, the thermal radiation is near infra-red thermal radiation and the transparent flexible platen is composed of silicone rubber. The bonding material may be an adhesive or a thermoplastic bonding material. A method of capacitively coupling a semiconductor chip to an electrical component with a pressure sensitive adhesive is also provided. The method includes compressing the chip by forcing a flexible platen of a bonding device into compressive engagement with the semiconductor chip.

### BACKGROUND OF THE INVENTION

1. Field of the Invention

The present invention relates generally to the assembly of electrical devices. More particularly, the present invention relates to the assembly of radio frequency identification (RFID) straps and/or tags.

2. Description of the Related Art

Pick and place techniques are often used to assemble electrical devices. Pick and place techniques typically involve complex robotic components and control systems that handle only one die at a time. Such techniques typically involve a manipulator, such as a robotic arm, to remove integrated circuit (IC) chips, or dies, from a wafer of IC chips and place them on a chip carrier or transport or directly to a substrate. If not directly mounted, the chips are subsequently mounted onto a substrate with other electrical components, such as antennas, capacitors, resistors, and inductors to form an electrical device.

One type of electrical device that may be assembled using pick and place techniques is a radio frequency identification (RFID) transponder. RFID inlays (also called inlets), tags, and labels (collectively referred to herein as “transponders”) are widely used to associate an object with an identification code. Inlays (or inlay transponders) are identification transponders that typically have a substantially flat shape. The antenna for an inlay transponder may be in the form of a conductive trace deposited on a non-conductive support. The antenna has the shape of a flat coil or the like. Leads for the antenna are also deposited, with non-conductive layers interposed as necessary. Memory and any control functions are provided by a chip mounted on the support and operatively connected through the leads to the antenna. An RFID inlay may be joined or laminated to selected label or tag materials made of films, papers, laminations of films and papers, or other flexible sheet materials suitable for a particular end use. The resulting RFID label stock or RFID tag stock may then be overprinted with text and/or graphics, die-cut into specific shapes and sizes into rolls of continuous labels, or sheets of single or multiple labels, or rolls or sheets of tags.

In many RFID applications, it is desirable to reduce the size of the electrical components as small as possible. In order to interconnect very small chips with antennas in RFID inlays, it is known to use a structure variously called “straps”, “interposers”, and “carriers” to facilitate inlay manufacture. Straps include conductive leads or pads that are electrically coupled to the contact pads of the chips for coupling to the antennas. These pads generally provide a larger effective electrical contact area than ICs precisely aligned for direct placement without an interposer. The larger area reduces the accuracy required for placement of ICs during manufacture while still providing effective electrical connection. IC placement and mounting are serious limitations for high-speed manufacture. The prior art discloses a variety of RFID strap or interposer structures, typically using a flexible substrate that carries the strap's contact pads or leads.

As noted above, RFID transponders include both integrated circuits and antennas for providing radio frequency identification functionality. Straps or interposers, on the other hand, include the integrated circuits but must be coupled to antennas in order to form complete RFID transponders. As used in the present patent application the term “device” refers both to an RFID transponder, and to a strap or interposer that is intended to be incorporated in an RFID transponder.

RFID devices generally have a combination of antennas and analog and/or digital electronics, which may include for example communications electronics, data memory, and control logic. For example, RFID tags are used in conjunction with security-locks in cars, for access control to buildings, and for tracking inventory and parcels. Some examples of RFID tags and labels appear in U.S. Pat. Nos. 6,107,920, 6,206,292, and 6,262,292, all of which are hereby incorporated by reference in their entireties.

An RFID device may be affixed to an item whose presence is to be detected and/or monitored. The presence of an RFID device, and therefore the presence of the item to which the device is affixed, may be checked and monitored by devices known as “readers.”

Typically, RFID devices are produced by patterning, etching or printing a conductor on a dielectric layer and coupling the conductor to a chip. As mentioned, pick and place techniques are often used for positioning a chip on the patterned conductor. Alternatively, a web containing a plurality of chips may be laminated to a web of printed conductor material. An example of such a process is disclosed in commonly assigned U.S. patent application Ser. No. 10/805,938, filed on Mar. 22, 2004.

The chips may be coupled to the conductor by any of a variety of suitable connecting materials and/or methods, such as, for example, by use of a conductive or non-conductive adhesive, by use of thermoplastic bonding materials, by use of conductive inks, by use of welding and/or soldering, or by electroplating. Typically, the material used for mechanically and/or electrically coupling the chip to the conductor requires heat and/or pressure to form a final interconnect—a process, in the case of adhesives, known as curing. Conventional thermocompressive bonding methods typically use some form of press for directing pressure and heat, via conduction or convection, to an RFID device assembly or web of RFID device assemblies. For example, pressure and heat may be applied by compressing the RFID device assembly or web of RFID device assemblies between a pair of heating plates, and relying on conduction through the various media, including chip and antenna, to heat the connecting material. Alternatively, one of the heating plates may be equipped with pins for selectively applying pressure and/or heat to certain areas (e.g. only the chips), and again relying on conduction to heat the connecting material. Alternatively, and especially in the case of solder, an oven may be used wherein the whole assembly is held at elevated temperature and via convection the solder reflows. In the latter case, pressure may not be applied to the device.

However, conventional thermocompression bonding devices have several disadvantages. For example, conventional thermocompression bonding devices are not well suited for applying uniform heat and uniform pressure simultaneously to many chips and/or to a very dense web of electrical devices, such as RFID device assemblies. Further, conventional thermocompression bonding devices using conduction or convection may not be suitable for high-speed operations. Both conduction and convection are relatively slow processes and apply heat indirectly to the connecting material (such as adhesive or solder). Thus, the entire electrical device assembly may be held for some time within the thermocompressive bonding device, for example 10 seconds, to allow the connecting material to achieve a desired temperature. For RFID device assembly, where commodity plastics are typically used as the carrying web (e.g. for the antenna), the temperature generally may not exceed the softening point of the plastic. Again, this limits the rate at which heat can be directed to the connecting material via conduction or convection.

Further, conventional thermocompression devices may not be easily adaptable to varying layouts and densities of chips and/or antennas and/or web configurations. For example, when a new chip or antenna lay-out is used, it is likely that the pin layout of a thermocompressive device must be changed to accommodate the new layout. Altering the pin layout of a conventional thermocompressive bonding device may be a very time intensive process resulting in significant down time of the bonding device.

From the foregoing it will be seen there is room for improvement of RFID devices and manufacturing processes relating thereto.

### SUMMARY OF THE INVENTION

According to an aspect of the invention, a method of thermocompressively bonding a semiconductor chip to an electrical component is provided comprising: positioning the semiconductor chip on the electrical component and heating a bonding material with a thermocompressive bonding device. The heating includes forcing at least one heating element of the bonding device into compressive engagement with the semiconductor chip. The forcing includes pressing down the at least one heating element with a resilient member of the bonding device.

According to another aspect of the invention, a method of thermocompressively bonding a semiconductor chip to an electrical component is provided comprising: positioning the semiconductor chip on the electrical component and heating a bonding material with a thermocompressive bonding device. The heating includes forcing a flexible platen of the thermocompressive bonding device into compressive engagement with the semiconductor chip and applying thermal radiation.

According to another aspect of the invention, a method of thermocompressively bonding a semiconductor chip to an electrical component is provided comprising: applying solder to at least one of the semiconductor chip or electrical component; positioning the semiconductor chip on the electrical component; and reflowing the solder with a thermocompressive bonding device. The reflowing includes forcing a flexible platen of the bonding device into compressive engagement with the semiconductor chip, and applying thermal radiation.

According to yet another aspect of the invention, a method of capacitively coupling a semiconductor chip to an electrical component is provided comprising: applying a pressure sensitive adhesive to at least one of a semiconductor chip and an electrical component; positioning the semiconductor chip on the electrical component; and coupling the semiconductor chip with the electrical component by compressing the adhesive with a bonding device. The compressing includes forcing a flexible platen of the bonding device into compressive engagement with the semiconductor chip.

To the accomplishment of the foregoing and related ends, the invention comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages, and novel features of the invention will become apparent from the following detailed description of the invention when considered in conjunction with the drawings.

### BRIEF DESCRIPTION OF THE DRAWINGS

In the annexed drawings, which are not necessarily according to scale,

FIG. 1 is a flowchart of a process for making electrical devices according to the present invention;

FIG. 2 is an oblique view of a thermocompressive bonding device according to the present invention;

FIG. 3 is a side view of a heating element of a thermocompressive bonding device according to the present invention;

FIG. 4 is a side view of a heating element of a thermocompressive bonding device according to the present invention;

FIG. 5 is a flow chart of a process for making electrical devices according to the present invention;

FIG. 6 is an oblique view of a thermocompressive bonding device according to the present invention;

FIG. 7 is a side view of a thermocompressive bonding device according to the present invention;

FIG. 8 is an oblique view of a thermocompressive bonding device according to the present invention;

FIG. 9 is a side view of a thermocompressive bonding device according to the present invention;

FIG. 10 is a graph of near infra-red (NIR) absorption rates of some exemplary materials relative to a black body emitter at 3200 Kelvin;

FIG. 11 is a flow chart of a process for making electrical devices according to the present invention;

FIG. 12 is a side view of a thermocompressive bonding device according to the present invention;

FIG. 13 is a flow chart of a process for making electrical devices according to the present invention;

FIG. 14 is a side view of a thermocompressive bonding device according to the present invention;

FIG. 15 is a side view of a thermocompressive bonding device according to the present invention;

FIG. 16 is an oblique view of a device produced by a method of the present invention;

FIG. 17 is a side view of a device produced by a method of the present invention; and

FIG. 18 is a side view of a device produced by a method of the present invention.

### DETAILED DESCRIPTION

A method of simultaneous thermocompressive bonding of multiple electrical devices using individual heating elements and a resilient member to force the individual heating elements into compressive engagement with the electrical devices is provided. The individual heating elements may be Curie-point heating elements or conventional resistive heating elements. A method of simultaneous thermocompressive bonding of multiple electrical devices using a transparent flexible platen and thermal radiation is also provided. In one embodiment, the thermal radiation is near infra-red thermal radiation and the transparent flexible platen is composed of silicone rubber. The bonding material may be an adhesive or a thermoplastic bonding material. A method of capacitively coupling a semiconductor chip to an electrical component with a pressure sensitive adhesive is also provided. The method includes compressing the chip by forcing a flexible platen of a bonding device into compressive engagement with the semiconductor chip.

Referring to FIG. 1, a method 100 of simultaneous thermocompressive bonding of multiple electrical devices in web format will be described. It will be appreciated that the electrical devices may be devices other than RFID devices. However, because this method is well suited to the manufacture of RFID devices, it will be described in the context of an RFID device manufacturing process.

The method 100 shown in FIG. 1 begins with providing a web of RFID strap leads, interposers, or antennas in process step 110. An adhesive, which may be anisotropic conductive paste (ACP) or film (ACF) or non-conductive epoxy (NCP), is applied to the web in step 120 using a suitable process such as printing, coating, or syringing. Alternatively, the adhesive may be applied to the chips, interposers or straps, or to both the web and the chips, interposers or straps. In process step 130, chips, interposers, or straps are provided. In process step 131, the chips, interposers or straps are coated with conductive materials (ACP, ACF) or non-conductive materials (NCP) using a suitable process such as printing, divers coating methods or syringing. Alternatively, solder may be applied to the chips, interposers or straps. In process step 140 the chips, interposers or straps are accurately placed on the web of antennas. The adhesive may optionally be partially cured to secure the chip, interposer or strap to the web before final binding. The chips, interposers, or straps are then bonded to the antennas by curing the ACP adhesive via thermocompression in step 150. Alternatively, the chips, interposers or straps are bonded to the antennas or strap leads in process step 150 through solder reflow, in which case further steps may follow for underfill and curing of the underfill. In addition to bonding chips, interposers or straps to antennas, it will be appreciated that method 100 is equally suitable for attaching a chip to strap leads (i.e., forming a strap) or attaching a strap to an interposer structure (i.e., forming an interposer).

The methods of the present invention are suitable for bonding a chip to an electrical component using a variety of bonding materials. As used herein, the term bonding refers to electrical and/or mechanical coupling of a chip to an electrical component. Adhesives may be thermocompressively cured by the methods of the present invention. As used herein, the term “cured” is intended to encompass bonding via adhesives wherein heat and pressure are applied to the adhesive thereby causing a chemical reaction resulting in cross-linking of the adhesive. Alternatively, a thermoplastic bonding material may be used to bond a chip to an electrical component. Thermoplastic bonding materials are typical melted and re-solidified thereby forming a mechanical and/or electrical bond. It will be appreciated that the methods of the present invention are not limited to the illustrated bonding materials, and that a wide variety of suitable bonding materials may be used with the methods of the present invention.

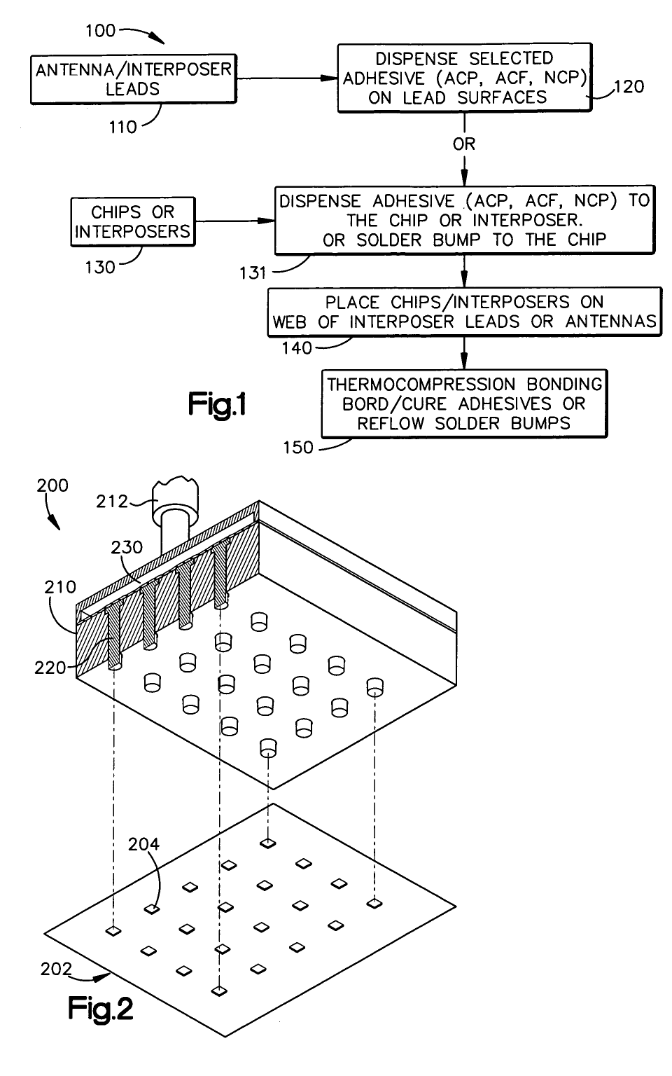

Turning to FIG. 2, a device and method for simultaneously bonding multiple electrical devices in web format using thermocompression will be described. The thermocompressive bonding device 200 includes a heater block 210 containing a plurality of heating elements 220. The heating elements 220 are fixed against lateral and transverse movement with respect to the heater block 210 and may protrude from the lower surface of the heater block 210 as shown in FIG. 2. The upper portion of the heater block 210 contains a deformable bladder 230. The bladder 230 may be filled with any suitable gas, liquid, or deformable solid. The bladder 230 is situated above the heating elements 220 and allows limited axial movement of the heating elements 220 with respect to the heater block 210 when the heater elements 220 are compressively engaged with another surface, such as a web of RFID devices. The heater block 210 is mounted in a press 212 or other device for raising and lowering the heater block 210 and providing a compressive force.

It will be appreciated that the deformable bladder 230 dampens the individual heater elements and also distributes pressure uniformly to the chips. Therefore, a suitable compressible solid material, such as a rubber pad, may be substituted for the deformable bladder. Alternatively, each heater element may be mounted in conjunction with a spring or other resilient device for absorbing shock.

The heater elements 220 of the present embodiment are preferably Curie Point self-regulating heating elements. An example of this type of heating element is disclosed in U.S. Pat. No. 5,182,427 and embodied in the SmartHeat® technology currently manufactured by Metcal of Menlo Park, Calif. Such heating elements typically comprise a central copper core having a coating of a magnetized nickel metal alloy. A high frequency current is induced in the heating element and, due to the skin effect, tends to flow in the nickel metal alloy coating. Joule heating in the relatively high electrical resistance nickel metal alloy causes the coating temperature to increase. Once the temperature of the nickel metal alloy coating reaches its characteristic Curie Point, a current is no longer in the nickel metal alloy coating and instead flows through the low resistance central copper core. The Curie Point temperature is essentially maintained at this point. Thus, when the high frequency current is switched on, the heating element heats rapidly to the Curie Point temperature and then self-regulates at that temperature. Curie Point self-regulating heating elements are advantageous because they are small, efficient, and temperature self-regulating, allowing a separate heating element to be assigned to each desired point of thermocompression. It will be appreciated that other heating elements, such as standard resistive heating elements, may also be used.

A multilane web of RFID devices is shown at 202 positioned below the heater block 210. The web of RFID device assemblies 202 may be IC chips positioned on a web of strap leads, interposers, or antenna structures preprinted with ACP adhesive. Alternatively, the web 202 of RFID device assemblies may be straps or interposers positioned on a web of antenna structures preprinted with ACP. Any suitable placement or insertion equipment may be used to place the chips, straps or interposers in the multilane web format. The web 202 is positioned with respect to the heater block 210 so that the RFID devices 204 on the web 202 are aligned with the heating elements 220. The heating elements 220 may be sized slightly larger than necessary so that some misalignment between the heating element 220 and the RFID device 204 may be acceptable. Once aligned, the press 212 lowers the heater block 210 into contact with the RFID 204 devices until a predetermined pressure is achieved.

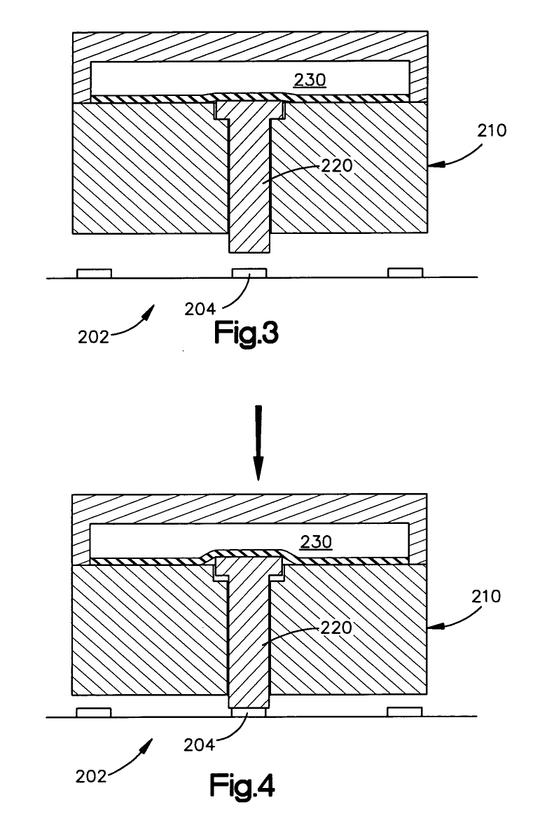

Turning to FIGS. 3 and 4, a close-up of a heating element 220 of a heater block 210 is shown. As previously set forth, the heating element 220 is fixed against lateral and transverse movement with respect to the heater block 210. The bladder 230 is disposed to provide a reactive force when the heating element 220 is compressed. As seen in FIG. 4, when the heater block 210 is lowered, the heating element 220 makes contact with the chips 204. As the heater block 210 is lowered further, the bladder 230 begins to deform, thereby exerting a reactive force on the heating element 220. It will be appreciated that, because the pressure in the bladder 230 is essentially equal at every point within the bladder, the pressure exerted on each heating element 220 by the bladder 230, and thus on each chip 204, is essentially equal. In this manner, the bladder 230 provides uniform pressure on each chip 204 and also dampens the impact of the heating elements 220 with the chips 204.

The bladder 230 also may compensate for variations in dimensions of the chip 204 and/or web 202 that would otherwise cause unequal pressure to be applied by rigidly affixed heating elements when the heater block 210 is lowered. This flexible application of pressure via the bladder 230 avoids crushing of the RFID devices to be bonded that may otherwise occur and results in a more efficient and uniform bonding of the RFID devices.

It will be appreciated that it may be desirable to monitor the pressure within the bladder 230 to ensure the proper pressure is applied to the RFID devices 204 for the proper amount of time. For example, the bladder pressure may be monitored and the length of time of compression adjusted according to known curing values thereby allowing more efficient use of the bonding device 200. In addition, it may also be desirable to include a means of increasing and decreasing the ambient pressure in the bladder 230 (i.e., the pressure in the bladder when the heater block 210 is not engaged with a web). For example, in some applications it may be desirable to have a higher ambient pressure in the bladder such that the bladder is exerting pressure on the heating elements when the heating elements are not compressively engaged with a device. In other applications, a lower ambient pressure may be desirable, such that the bladder exerts little or no pressure on the heating elements until the heating elements are compressively engaged with a device. Devices for preventing over-pressurization of the bladder, such as relief valves, may also be employed to prevent damage to a web of RFID devices during the thermocompressive bonding process.

Depending on the configuration of the heating elements 220 and the configuration of the RFID devices 204 on the web 202, the RFID devices 204 may be cured in one or more sets. For example, a web 202 of RFID devices 204 may have eight rows of RFID devices, but a thermocompressive bonding device 210 of the present invention may be equipped with only four rows of heating elements. Thus, as a web of RFID devices progresses through the thermocompressive bonding device, a first set of four rows of RFID devices are cured in a first step. The web and/or thermocompressive bonding device 210 is then repositioned, or indexed, to the remaining four lanes of RFID devices, and the remaining devices within those lanes are cured in a second step. It will be appreciated that a wide variety of sizes, quantities, and configurations of heating elements are possible. It will further be appreciated that the size, quantity, and/or configuration of the heating elements may correspond to the dimensions of the web and the layout thereon of the elements to be thermocompressively cured.

As stated, the flexible application of pressure in the present embodiment may prevent potential crushing of components that may otherwise occur without flexible pressure application, such as in conventional thermocompression bonding devices using flat compression plates. Further, the flexible pressure application may compensate for variations in pressure across the electrical devices and/or web. Thus, substantially uniform pressure may be provided to each electrical device during curing, which may lead to more consistent bonding. The individual heating elements are also more readily thermally regulated than a single larger thermal mass. Thus, more precise application of heat is possible.

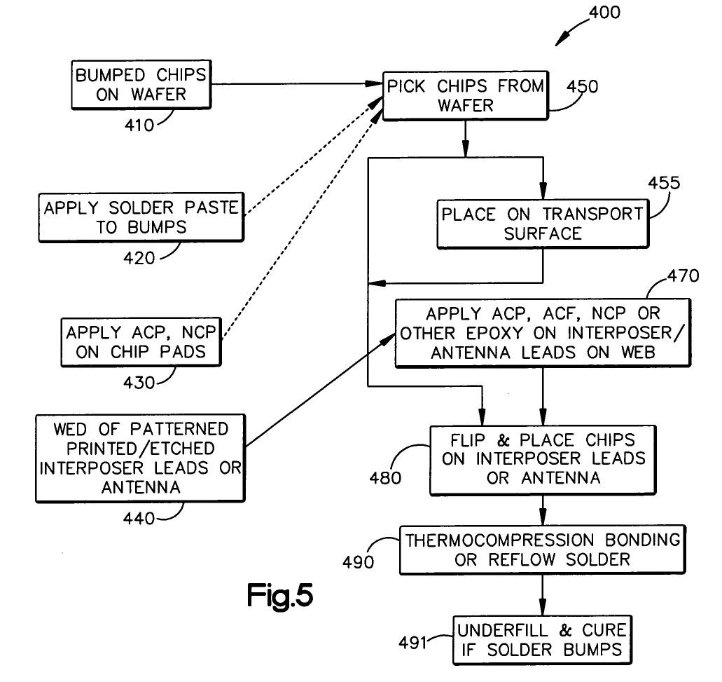

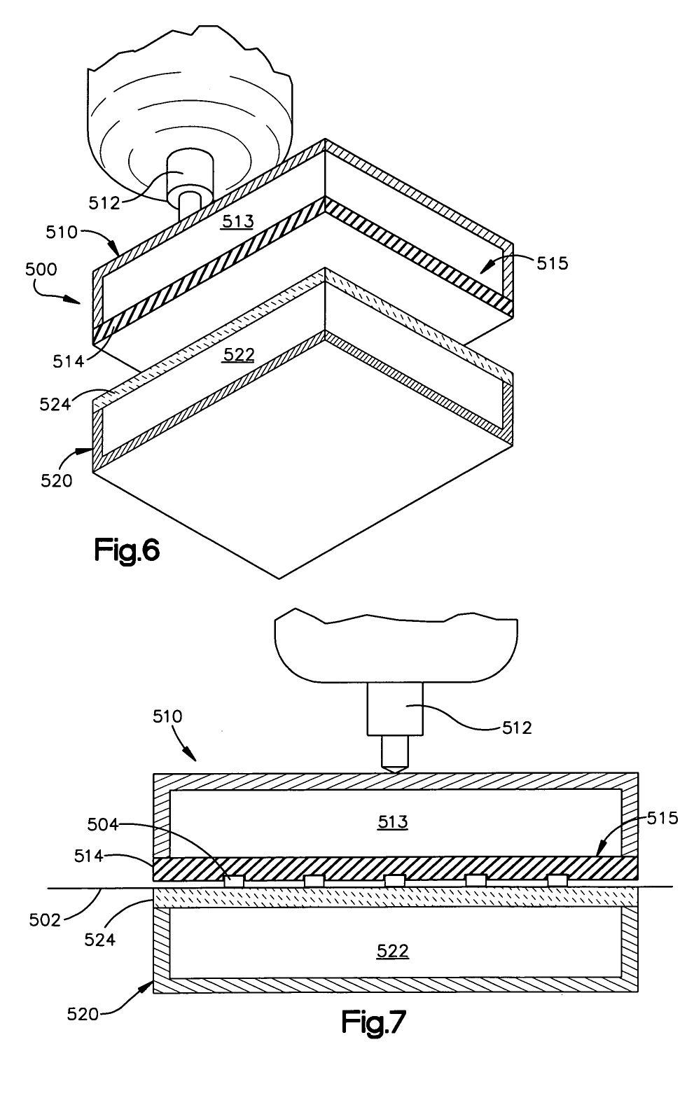

Turning to FIG. 5, a method 400 of producing an RFID device using a flip chip manufacturing method and the thermocompressive bonding device of FIGS. 2-4 will be described. The method 400 begins with process step 410 where a wafer of bumped chips is presented. In process step 420, solder paste is applied to the chips. Alternatively, an adhesive such as ACP, ACF or NCP may be applied to the chips in process step 430. The assembly process starts at process step 450 by picking chips from the wafer and placing the chips on a transport surface in process step 455. Alternatively, the chips may be placed directly on the straps, interposers or antenna structures of a web of strap leads, interposers, or antenna structures. A flux material or adhesive may optionally be printed to the strap leads, interposers, or antenna structures in process step 470. In process step 480, the chips are picked from the transport surface, flipped over, and placed on the web of strap leads, interposers, or antenna structures with the chip pads (or solder bumps) on each chip contacting the strap leads or antenna structures. Alternatively, the chips may be placed directly on strap leads, interposers or antennas without first being placed on a transport surface as in process step 455. The chips are then bonded to the strap leads, interposers, or antenna structures in process step 490 either by thermocompressively curing the adhesive or by reflowing the solder bumps. The thermocompressive bonding device shown in FIGS. 2-4, or the NIR thermocompressive of FIGS. 6-9 described herein, may be used in process step 490 to cure the adhesive or to reflow the solder bumps. It will be appreciated that process step 491 may optionally be performed when solder is used. In process step 491, an underfill may be applied to enhance the mechanical connection between the chips and the strap leads, interposers, or antenna structures. Alternatively, a no-flow or low-flow underfill may be dispensed prior to process step 490.

Turning now to FIGS. 6 and 7, another device and method for simultaneous thermocompressive bonding of multiple electrical devices in web format will be described. In FIG. 6, the thermocompressive bonding device 500 includes an upper plate 510 having a reflector 515 and a silicone rubber platen 514 or other flexible thermal radiation transparent material. The upper plate 510 is mounted to a press 512 or other device for raising and lowering the upper plate 510 to provide a compressive force. The upper plate may optionally include a deformable material insert 513, possibly composed of rubber. A lower plate 520 includes one or more thermal radiation heating elements 522 and a quartz platen 524.

The use of thermal radiation as the heat source in the thermocompression bonding process of the invention offers various advantages. Radiant energy heat transfer, in comparison to conductive and convective heat transfer, is capable of achieving significantly higher heat fluxes. Radiant energy can provide extremely rapid heating because of the high speed of light and the possibility of applying heat directly to the material to be heated. Controlled radiant heating can achieve various process advantages, such as reduction of the cooling requirements of the system, and improved precision via coordination between localized heat and pressure.

As stated, radiant heating may be applied directly to the material to be heated. The ability to precisely apply heat directly to areas to be heated is advantageous because less overall heat energy may be required as compared to conductive or convective heating methods. Further, because less overall heat energy is applied, once the bonding process is complete the materials and/or structure cool more rapidly.

Radiant energy heating can be combined with other modes of heat transfer, for example conductive heating, to achieve advantageous effects. For example, thermal radiation heat transfer may be used to heat structures of the system (particularly the silicon chips), which in turn may transfer heat by conduction to the material to be cured via thermocompression. Thus, the thermal radiation may not be applied directly to the material to be cured, but rather indirectly via thermal conduction from an adjacent structure such as a chip or antenna structure.

As described in greater detail below, the radiant energy may pass through a relatively radiantly-transparent material before impinging upon and being absorbed by a relatively radiantly-absorptive material. As used herein, a relatively radiantly-transparent material (also referred to a “transparent material”) refers to a material that is less absorptive to the radiant energy than the relatively radiantly-absorptive material (also referred to as an “absorptive material”).

Suitable thermal radiation energy may be utilized for heating in this embodiment by using relatively-radiantly-transparent material for the upper platen and relatively-radiantly-absorptive materials for one or more of the surfaces to be bonded. For example, by exposing a relatively-radiantly-absorptive chip, positioned on an electrical component with an appropriate adhesive, to near infra-red (NIR) thermal radiation, the chip is heated which thereby may heat and cure the adhesive. Other wavelengths of thermal radiation may also be utilized with other materials in this embodiment. For example, ultraviolet (UV) or microwave energy may be suitable forms of energy for some applications. Electron beam curing may also be suitable for use with some materials. In general, the form of thermal radiation used will be dictated by the absorptive or non-absorptive properties of the component materials and/or the type of adhesive to be cured.

A preferred line of commercially available high-energy NIR systems is supplied by AdPhos AG, Bruckmühl-Heufeld, Germany (AdPhos). AdPhos infrared heating systems provide durable, high energy heating systems; and an AdPhos lamp acts as a blackbody emitter operating at about 3200K. Other radiant heaters and emitters that provide suitable thermal energy are available from various major lamp manufacturers (including Phillips, Ushio, General Electric, Sylvania, and Glenro). For example, these manufacturers produce emitters for epitaxial reactors used by the semiconductor industry. All of these emitters have temperatures over 3000 K. More broadly, however, suitable NIR sources may be emitters with temperatures over about 2000 K. An advantage of the AdPhos system is that whereas most such high energy NIR lamps have a rated life of less than 2000 hours, the AdPhos NIR systems are designed for 4000 to 5000 hours of service life. The radiant energy emissions of the AdPhos NIR lamps have most of their energy in a wavelength range of between 0.4 to 2 microns with the peak energy delivered around 800 nm, which is shifted to a lower wavelength than short-wave and medium-wave infrared sources, providing a higher energy output and other advantages in absorption of the thermal radiation as explained below.

In FIG. 7, a multilane web 502 of RFID devices 504 is positioned between the upper plate 510 and the lower plate 520. The web 502 of RFID devices 504 may be IC chips positioned on a web of strap leads, interposers, or antenna structures preprinted with an adhesive. The quartz platen 524 may be coated with Teflon or other suitable polymer. A polymer with a high glass transition temperature (T_{g}), e.g. Teflon, sheet or film may be used instead of the coating. The press 512 lowers the upper plate 510 until the flexible platen 514 on the upper plate 510 is forced, to a predetermined pressure, against the RFID devices 504. As shown in FIG. 7, as the web 502 of RFID devices is compressed between the flexible platen 514 and the quartz platen 524, the flexible platen 514 deforms around the chips or devices 504, thereby distributing pressure substantially evenly across the chips or devices, and also thereby compensating for pressure variations. The NIR heating element 522 is then activated and the RFID devices 504 are heated to a suitable temperature thereby thermocompressively curing the adhesive. The upper plate 510 may include a surface for reflecting the thermal radiation back towards the chips.

It will be appreciated that the flexible platen 514, web 502, and quartz platen 524 are relatively-radiantly-transparent and thus, when exposed to NIR radiation, the temperature of the platens will not increase significantly. However, because the RFID devices 504 and/or chips absorb NIR radiation, the RFID devices 504 and/or chips will heat rapidly when exposed to NIR radiation. As the RFID devices 504 and/or chips are heated by the NIR lamps 522, the adhesive at the interface of the chip or strap and surface to which it is mounted is also heated, thereby curing the adhesive. The adhesive may generally be heated via conduction from the heated chip. It will be appreciated that some antenna structures may also be heated by NIR radiation and therefore will also conduct heat to the adhesive to be cured. Alternatively, some adhesives may absorb NIR radiation and may therefore be heated directly by NIR radiation.

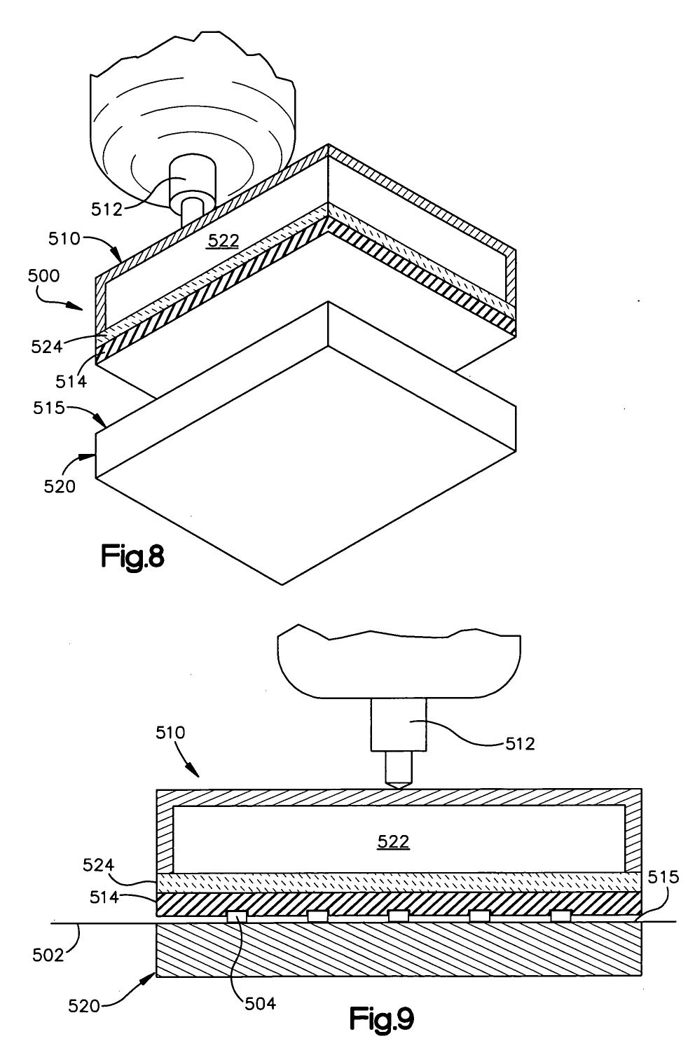

FIG. 8 shows another configuration of the NIR thermocompressive bonding device. The thermocompressive bonding device 500 includes an upper plate 510 and a lower plate 520. The upper plate 510 in this embodiment includes one or more thermal radiation heating elements 522, a quartz platen 524, and a transparent flexible platen 514. The lower plate 520 serves as a reaction surface against which the upper platen 510 may be compressed. The top surface of the lower plate 520 may be coated with Teflon or other suitable polymer. Alternatively, a Teflon sheet or film may be used. The lower plate 520 may also include a reflective surface 515.

In FIG. 9, a web of RFID device assemblies 502 is compressed between the upper platen 510 and the lower platen 520. The flexible platen 514 is deformed around the RFID devices 504 on the web thereby providing essentially uniform pressure to the RFID devices 504. The relatively radiantly-transparent quartz platen 524 and flexible platen 514 allow the NIR or other thermal radiation from the thermal radiation heating element 522 to reach the RFID device 504, thereby heating the devices and curing the adhesive.

Turning to FIG. 10, a graph is shown of the relative NIR radiation absorption rates of various exemplary materials that may be used in the present invention. The graph shown in FIG. 10 is for explanatory purposes and the materials shown are merely exemplary materials that may be used to practice the present invention. The materials are in no way intended to limit the materials that may be used to practice the present invention. From the graph it can be seen that, over most of the wavelength spectrum, the exemplary materials that may be used in the system (clear silicone, polysulfone, PMMA) absorb NIR radiation at a much lower rate than the polished silicon of which a chip may be comprised. The higher rate of absorption of NIR radiation by the polished silicon material allows the chips to be rapidly heated by NIR radiation while the substrate material remains relatively cool. It will be appreciated that many polymers, such as PEEK or PEN, are available for use as the flexible platen material as most polymers are generally NIR transparent. However, the flexible platen material should be able to withstand temperatures greater than that to which the chip will be heated.

The thermal radiation thermocompression bonding devices achieve several advantages. For example, unlike conventional thermocompressive bonding devices which require indexing the RFID devices on the web to the heating element(s) to provide heat and/or pressure, the present embodiment provides pressure uniformly across the RFID devices and selectively heats only the portions of the RFID device 504 and/or web 502 that absorb thermal radiation. Thus, no indexing of the RFID devices 504 to a heating element is required. In addition, because only thermal radiation absorptive materials are heated, thermal radiation heating is more localized and precise than conductive or convective heating processes. Heat is directed only to the portions of the web that absorb thermal radiation and, thus, the entire web is not heated. Therefore, materials may be chosen for the various components of an electrical device based upon which components will be heated. This has the advantage of decreasing the risk of damage to an electrical device due to excessive heat. Further, because only the chips are heated, the majority of the components remain relatively cool and therefore warping and/or other heat degradation is less likely.

Thermal radiation heating is also typically more efficient than conductive or convective heating means, and produces a high temperature with a relatively low heat energy input as compared with conductive or convective heating processes. Thermal radiation heating can be quickly applied and removed allowing rapid heating and cooling. Thus, the time required to achieve a thermocompressive bond using thermal radiation heating will generally be less than that of other heating processes. The flexible application of pressure by the flexible platen decreases the risk of damage to the RFID devices that may occur using conventional thermocompressive bonding methods. Further, because the flexible platen is flexible it is readily adaptable to new web formats, device densities, and device dimensions. Unlike conventional thermocompressive bonding methods, the flexible platen of the present invention may be used to thermocompressively bond electrical devices of different dimensions and/or webs having different densities and formats of electrical devices without being retooled. Thus, because uniform pressure and uniform heat may be supplied to the entire area below the thermal radiation heating element(s) regardless of the density, thickness, or positions of the devices on the web, the thermocompressive bonding device of the present embodiment is highly adaptable to a wide variety of RFID patterns and densities. Further, the present embodiment may allow a much greater area to be cured simultaneously thereby increasing the rate that electrical devices may be cured.

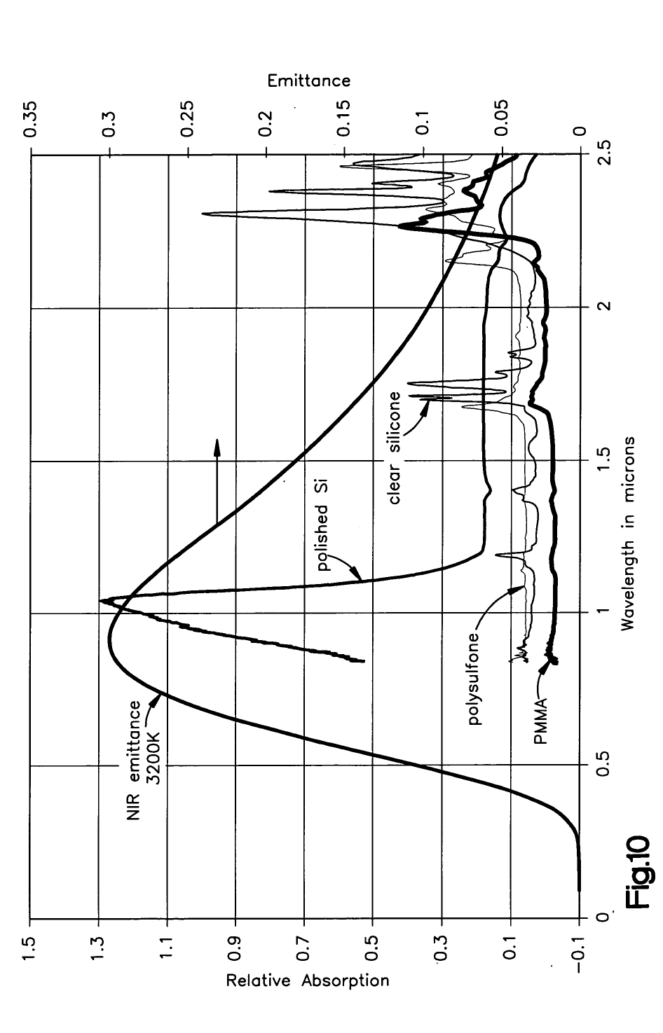

The thermocompression bonding methods described above may be used to bond chips to printed or etched straps and/or antennas. In FIG. 11 a method 600-a for producing a web of electrical devices is presented. In process step 601, a wafer of bumped chips is provided. In process step 602, adhesive, for example ACP, ACF, or NCP is applied to either the chips or the conductive printed or etched elements of straps or antennas. In process step 604 the chips are picked from the wafer, flipped and placed on straps or antennas in process step 605. The straps or antennas may be presented on a web of a selected substrate as shown in process step 603. In process step 606, the web, including the plurality of chips placed on the straps and/or antennas, is carried into an NIR thermocompression bonding device wherein the plurality of chips will be bonded to the straps and/or antennas.

The thermocompression bonding of the chips to straps and/or antennas may be performed using the thermocompressive bonding methods and devices of the present invention. For example, the NIR thermocompressive bonding device discussed above with regard to FIGS. 6-7 may be used in process step 606. As shown in FIG. 12, an NIR thermocompressive bonding device 500 having an NIR heating element 520 and a flexible platen 530 is compressed against a chip 704 on a web 702 having patterned conductors, or other electrical components. The flexible platen 530 is deformed around the chip 704 thereby providing pressure thereto. As seen in FIG. 12, the chip pads 706 on the chips 704 are contacting the printed/etched conductive material 708 on the web 702. When the NIR heating element 520 is activated, the chip 704 and the pads 706 and consequently, the adhesive (ACP, ACF or NCP) under the chip, are heated by the NIR radiation. The heat and pressure thereby bond the pads 706 of the chip 704 to the printed/etched conductive material 708 together (directly in the case of NCP or through the use of Z direction conductive particles in ACP or ACF). The NIR heating element 520 may then be deactivated allowing the adhesive to solidify rapidly thereby electrically and mechanically coupling the pads 706 and printed/etched conductive material on web 702. The thermocompressive bonding device is then opened allowing the web 702 to move with the chips 704 now bonded electrically and mechanically to the straps and/or antennas on the web 702.

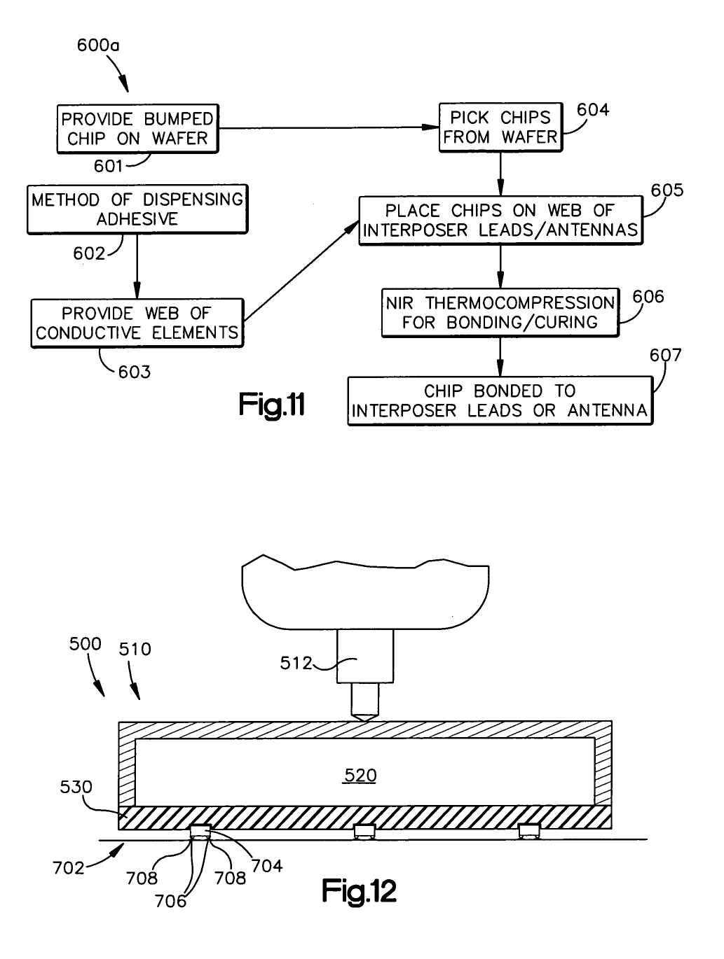

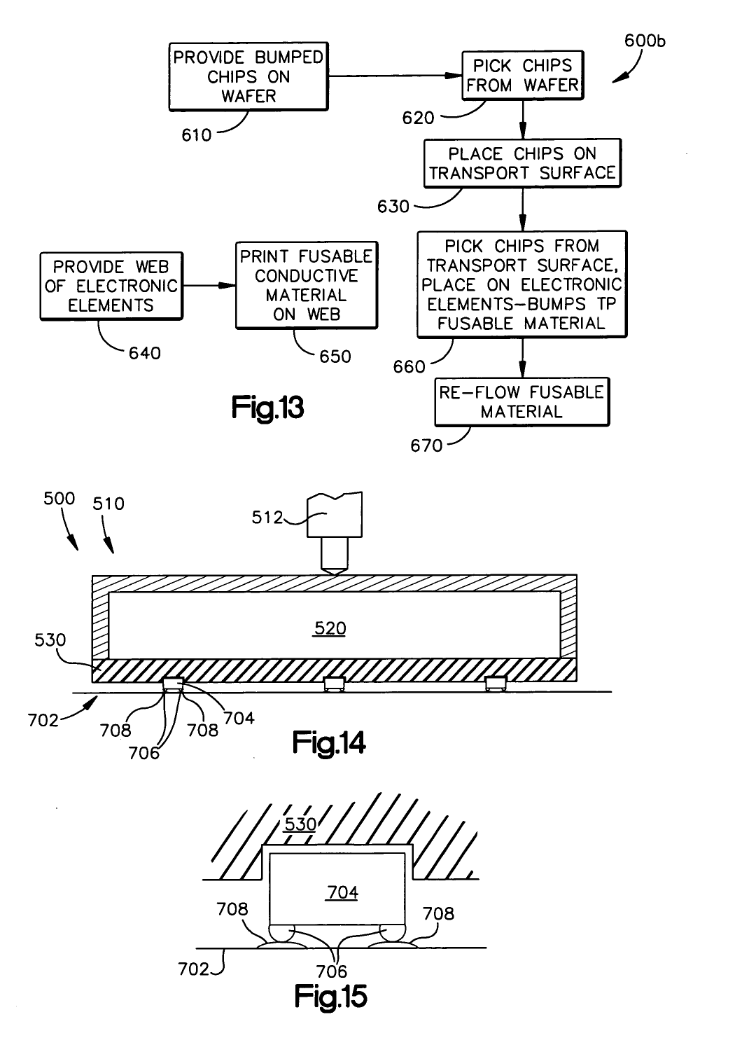

The thermocompression bonding methods described above are also suitable for reflowing fusible conductive material (e.g. solder). In FIG. 13, a method 600b for producing a web of electrical devices is shown. In process step 610, a wafer of bumped chips is provided. The chips are picked from the wafer in process steps 620 and are optionally placed on a transport surface in process step 630. In process step 640 a web of electrical components, such as printed or etched conductors, is provided. A fusible conductive material is printed on the web in process step 650. A flux material may optionally be applied over the fusible conductive material after process step 650 to ensure proper flow of the fusible conductive material during reflow. In addition, an adhesive may be printed or otherwise deposited on the web to temporarily secure the chip to the electrical component prior to reflow of the solder in process step 670. The chips are then placed on the web in process step 660 directly from the wafer, or optionally from the transport surface, with the bumps contacting the fusible conductive material on the web. The fusible conductive material is then reflowed in process step 670 thereby electrically coupling the chip to the electrical component.

Reflowing the fusible conductive material may be done using the thermocompressive bonding methods of the present invention. For example, after process step 660, the web may be advanced through a thermocompressive bonding device such as the NIR thermocompressive bonding device discussed above with regard to FIGS. 6-7. As shown in FIG. 14, an NIR thermocompressive bonding device 500 having an NIR heating element 520 and a flexible platen 530 is compressed against a chip 704 on a web 702 having patterned conductors, or other electrical components. The flexible platen 530 is deformed around the chip 704 thereby providing pressure thereto. As seen in FIG. 15, the solder bumps 706 on the chips 704 are contacting the printed fusible conductive material 708. When the NIR heating element 520 is activated, the chip 704 and/or solder bumps 706 will be heated by the NIR radiation thereby causing the solder bumps 706 and fusible conductive material 708 to reflow. The NIR heating element 520 will then be deactivated thereby allowing the solder 706 and fusible conductive material 708 to solidify thereby electrically and mechanically coupling the chip 704 to the electrical component on the web 702. An underfill material may then be applied to enhance to mechanical connection of the chip to the electrical component. It will be appreciated that the fusible conductive material 708 may not be required in all applications as the solder 706 alone may provide adequate electrical coupling of the chip to the electrical component.

Additional process steps in any one of the embodiments above can be executed depending on the application and materials used. For example, it may be desirable to dispense fusible conductive material (i.e., solder paste) to the chips prior to removal from the wafer. When using solder paste to couple the chips to strap leads, interposers, or antenna structures, it may be desirable to apply a no-flow or low-flow underfill prior to reflowing the solder to enhance the mechanical connection between the chips and the strap leads, interposers, or antenna structures. However, when using an ACP or NCP adhesive to couple the chips to the strap leads, interposers, or antenna structures, no underfill is typically required. In all of the methods described above, it may be advantageous to print adhesive to the web of strap leads, interposers, or antenna structures for the purpose of holding the chips in place after placement on the web but before the chips are bonded thereto.

The embodiments of the invention are also well suited to processes for making capacitively coupled inlays. For example, a pressure sensitive adhesive (PSA) may be used instead of ACP to couple the chip to the strap leads or antenna structure. The thermocompressive bonding devices disclosed previously may be used without heat to apply only pressure to the RFID device assemblies (i.e., the heat source is not activated). In this manner, capacitively coupled RFID devices may be produced. FIG. 16 shows an example of such a device, wherein antenna portions 822 are capacitively coupled to the strap leads 810 of an RFID strap 812 with a pressure sensitive adhesive or by other suitable means.

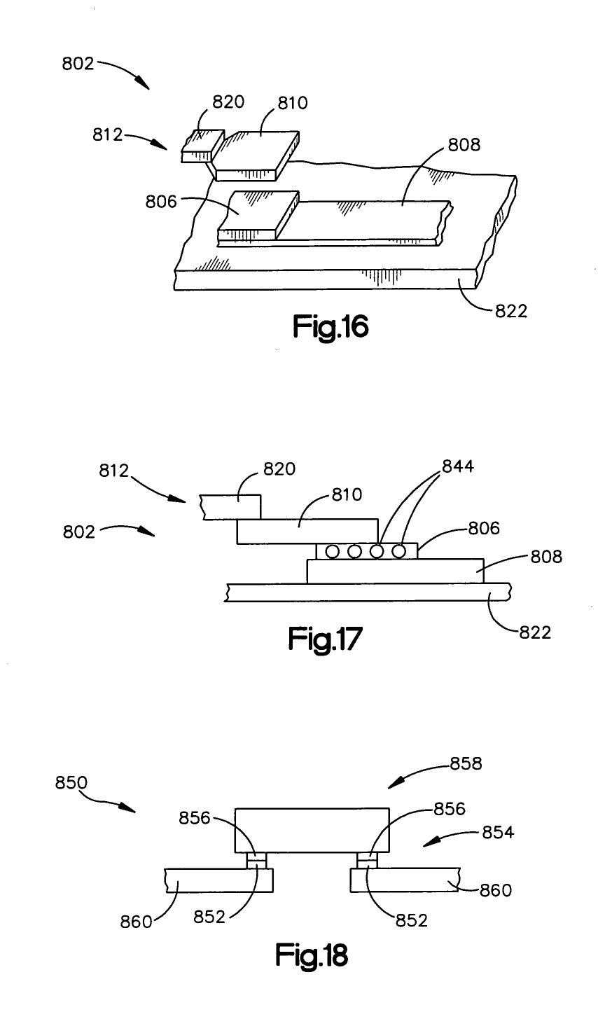

FIG. 17 illustrates another variation of a capacitively coupled inlay that may be produced by the methods of the present invention. The RFID device 802 includes an antenna structure 808 and a strap 812. A gap between the conductive strap lead 810 and the antenna structure 808 is maintained by spacers 844 that are part of the dielectric pad 806. The spacers 844 may be utilized in the dielectric pad 806 in conjunction with a non-conductive polymer. The spacers 844 may be pre-blended in the polymer material. Alternatively, the spacers may be dry-sprayed onto a non-conductive polymer that has already been applied to the antenna 808 and/or the conductive strap lead 810. It will be appreciated that the spacers 844 may also be utilized in conjunction with other dielectric materials, such as pressure sensitive adhesives. Examples of suitable spacers include Micropearl SP-205 5 μm spacers available from Sekisui Fine Chemical Co. of Japan, and 7.7 μm fiber spacers (product 111413) available from Merck. It will be appreciated that using the spacers 844 may aid in obtaining accurate and consistent spacing between the antenna 808 and the conductive strap leads 810 of the RFID devices 800.

FIG. 18 illustrates yet another type of capacitively coupled RFID device 850 that may be produced by the methods of the present invention. In FIG. 16, a strap or interposer 850 is coupled to conductive strap leads 860 with dielectric pads 852 making a capacitive coupling 854 between contacts 856 of a chip 858 and conductive strap leads 860. A pressure sensitive adhesive may be at the interface of the contacts 856 of the chip 858 and the dielectric pads 852 to bond the components together. Alternatively, ACP adhesive may be used to couple the chip 858 to the strap leads 860.

It will be appreciated that the embodiments of the present invention allow thermocompressive bonding and/or coupling of very dense arrangements of semiconductor chips and electrical components in web format. As previously set forth, the present invention is capable of bonding and/or coupling chips to electrical components in multi-row format on a web. The methods of the present invention may facilitate bonding of electrical devices on a web having an inter-chip pitch of less than 7 millimeters, and preferably less than 5 millimeters. The inter-chip pitch is the spacing between adjacent chips on the web. The ability to bond very dense webs (i.e., low inter-chip pitch) of devices permits the use of higher quality substrates because less substrate material is wasted. Thus, materials that were previously cost prohibitive to use as substrate material may be used in the methods of the invention. There may be advantages to using some higher cost materials, such as Kapton. For example, the high T_{g} of Kapton makes it particularly well suited for use in thermal bonding processes as it can withstand higher temperatures than conventional materials.

However, it will also be appreciated that the thermal radiation embodiment of the present invention may not require the use of higher cost substrate materials, such as Kapton. Due to the precise and localized application of heat through thermal radiation, the adhesive may cure without significant heating of the substrate material. Therefore, less expensive substrate materials may be used. Regardless of the type of substrate material used, the methods of the invention allow thermocompressive bonding of very dense arrangements of electrical devices and therefore reduce the amount of substrate material required per device. In this manner, the methods of the invention allow production of electrical devices at a lower cost.

The thermocompression bonding methods and devices of the present invention may be used with existing electrical device manufacturing machines, for example the DS9000 Tape Reel System built by Besi Die Handling, Inc. The DS9000 is capable of placing 9000 units per hour. The methods of the present invention may be used in conjunction with such a machine to produce RFID devices at very high speed and low cost.

Certain modifications and improvements will occur to those skilled in the art upon a reading of the foregoing description. It should be understood that the present invention is not limited to any particular type of wireless communication device, or straps. For the purposes of this application, couple, coupled, or coupling are broadly intended to be construed to include both direct electrical and reactive electrical coupling. Reactive coupling is broadly intended to include both capacitive and inductive coupling. One of ordinary skill in the art will recognize that there are different manners in which these elements can accomplish the present invention. The present invention is intended to cover what is claimed and any equivalents. The specific embodiments used herein are to aid in the understanding of the present invention, and should not be used to limit the scope of the invention in a manner narrower than the claims and their equivalents.

Although the invention has been shown and described with respect to a certain embodiment or embodiments, it is obvious that equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the invention. In addition, while a particular feature of the invention may have been described above with respect to only one or more of several illustrated embodiments, such feature may be combined with one or more other features of the other embodiments, as may be desired and advantageous for any given or particular application.

1. A method of thermocompressively bonding a semiconductor chip to an electrical component comprising:
positioning the semiconductor chip on the electrical component; and
heating a bonding material with a thermocompressive bonding device;
wherein the heating includes forcing at least one heating element of the bonding device into compressive engagement with the semiconductor chip; and
wherein the forcing includes pressing down the at least one heating element with a resilient member of the bonding device.

2. The method of claim 1, wherein the bonding material includes an adhesive applied to at least one of the semiconductor chip and electrical component.

3. The method of claim 1, wherein the bonding material includes a thermoplastic bonding material.

4. The method of claim 1, wherein the at least one heating element includes a Curie Point self-regulating heating element.

5. The method of claim 1, wherein the at least one heating element includes a resistive heating element.

6. The method of claim 1, wherein the resilient member includes a deformable bladder.

7. The method of claim 1, wherein the resilient member includes a rubber pad.

8. The method of claim 1, wherein the resilient member includes a spring.

9. The method of claim 1, wherein the electrical component includes a strap.

10. The method of claim 1, wherein the electrical component includes an antenna structure.

11. The method of claim 1, wherein a plurality of semiconductor chips are simultaneously thermocompressively bonded to a plurality of electrical components on a multilane web.

12. The method of claim 1, wherein the positioning includes aligning a plurality of semiconductor chips with a plurality of electrical components on a web.

13. The method of claim 12, wherein an inter-chip pitch between adjacent chips on the web is less than 7 millimeters.

14. The method of claim 12, wherein an inter-chip pitch between adjacent chips on the web is less than 5 millimeters.

15. A method of thermocompressively bonding a semiconductor chip to an electrical component comprising:
positioning the semiconductor chip on the electrical component; and
heating a bonding material with a thermocompressive bonding device, wherein the heating includes:
forcing a flexible platen of the thermocompressive bonding device into compressive engagement with the semiconductor chip; and
applying thermal radiation.

16. The method of claim 15, wherein the bonding material includes an adhesive that is applied to at least one of the semiconductor chip and electrical component.

17. The method of claim 15, wherein the bonding material includes a thermoplastic bonding material.

18. The method of claim 15, wherein the flexible platen is relatively radiantly-transparent.

19. The method of claim 17, wherein the flexible platen includes silicone rubber.

20. The method of claim 17, wherein the flexible platen includes Teflon.

21. The method of claim 15, wherein a plurality of semiconductor chips are thermocompressively bonded to a plurality of electrical components on a multilane web.

22. The method of claim 15, wherein the positioning includes aligning a plurality of semiconductor chips with a plurality of electrical components on a web.

23. The method of claim 22, wherein an inter-chip pitch between adjacent chips on the web is less than 7 millimeters.

24. The method of claim 22, wherein an inter-chip pitch between adjacent chips on the web is less than 5 millimeters.

25. The method of claim 15, wherein the electrical component includes a strap.

26. The method of claim 15, wherein the electrical component includes an antenna structure.

27. (canceled)

28. The method of claim 15, wherein the thermal radiation includes near infra-red radiation.

29. The method of claim 15, wherein the thermal radiation includes microwave radiation.

30. The method of claim 15, wherein the thermal radiation includes ultraviolet radiation.

31. The method of claim 15, wherein the thermal radiation includes an electron beam.

32. The method of claim 15, wherein the semiconductor chip is relatively radiantly-absorptive.

33. A method of thermocompressively bonding a semiconductor chip to an electrical component comprising:
applying solder to at least one of the semiconductor chip or electrical component;
positioning the semiconductor chip on the electrical component; and
reflowing the solder with a thermocompressive bonding device, wherein the reflowing includes:
forcing a flexible platen of the bonding device into compressive engagement with the semiconductor chip, and
applying thermal radiation.

34. The method of claim 33, wherein the flexible platen includes relatively radiantly-transparent.

35. The method of claim 34, wherein the flexible platen includes silicone rubber.

36. The method of claim 34, wherein the flexible platen includes teflon.

37. The method of claim 33 wherein a plurality of semiconductor chips are thermocompressively bonded to a plurality of electrical components on a multilane web.

38. The method of claim 33, wherein the positioning includes aligning a plurality of semiconductor chips with a plurality of electrical components on a web.

39. The method of claim 38, wherein an inter-chip pitch between adjacent chips on the web is less than 7 millimeters.

40. The method of claim 38, wherein an inter-chip pitch between adjacent chips on the web is less than 5 millimeters.

41. The method of claim 33, wherein the electrical component includes a strap.

42. The method of claim 33, wherein the electrical component includes an antenna structure.

43. The method of claim 33, wherein the thermal radiation includes near infra-red radiation.

44. The method of claim 33, wherein the thermal radiation includes microwave radiation.

45. The method of claim 33, wherein the thermal radiation includes ultraviolet radiation.

46. The method of claim 33, wherein the thermal radiation includes an electron beam.

47. The method of claim 33, wherein the semiconductor chip is relatively radiantly-absorptive.

48. A method of capacitively coupling a semiconductor chip to an electrical component comprising:
applying a pressure sensitive adhesive to at least one of a semiconductor chip and an electrical component;
positioning the semiconductor chip on the electrical component; and
coupling the semiconductor chip with the electrical component by compressing the adhesive with a bonding device;
wherein the compressing includes forcing a flexible platen of the bonding device into compressive engagement with the semiconductor chip.

49. The method of claim 48, wherein the flexible platen includes silicone rubber.

50. The method of claim 48, wherein the flexible platen includes Teflon.

51. The method of claim 48, wherein the electrical component includes a strap.

52. The method of claim 48, wherein the electrical component includes an antenna structure.

53. The method of claim 48, wherein a plurality of semiconductor chips are coupled to a plurality of electrical components on a multilane web.

54. The method of claim 48, wherein the positioning includes aligning a plurality of semiconductor chips with a plurality of electrical components on a web.

55. The method of claim 54, wherein an inter-chip pitch between adjacent chips on the web is less than 7 millimeters.

56. The method of claim 54, wherein an inter-chip pitch between adjacent chips on the web is less than 5 millimeters.

57. The method of claim 1, wherein the resilient member includes a flexible platen.

58. The method of claim 48, wherein the semiconductor chip is an interposer including interposer leads mounted to the chip.

59. The method of claim 48, wherein the adhesive is an epoxy.

60. The method of claim 48, wherein the adhesive is thermoplastic adhesive.
